(19) United States
(12) Patent Application Publication
(10) Pub. No.: US 2026/0156947 A1
(43) Pub. Date: Jun. 4, 2026

(54) ELECTROSTATIC DISCHARGE DEVICE WITH BACKSIDE LATCH-UP IMMUNITY

(71) Applicant: INTERNATIONAL BUSINESS MACHINES CORPORATION, ARMONK, NY (US)

(72) Inventors: Masoud Zabihi, Schenectady, NY (US); Ruilong Xie, Niskayuna, NY (US); Robert Gauthier, Williston, VT (US); Anindya Nath, Watervliet, NY (US); Anthony I-Chih Chou, Guilderland, NY (US)

(21) Appl. No.: 18/955,869

(22) Filed: Nov. 21, 2024

(51) Int. Cl. H10D 89/60

(52) U.S. Cl. CPC H10D 89/611

(57) ABSTRACT

A semiconductor device includes a passive device including a first backside contact on a first side of the passive device, a second backside contact on a second side of the passive device, a first doped region over the first backside contact and on a backside of the passive device, a second doped region over the second backside contact and located on the backside of the passive device, a first well region over the first doped region, a second well region over the second doped region and a shallow trench isolation (STI) above the first well region and the second well region.

### BACKGROUND

### Technical Field

The present disclosure generally relates to semiconductors, and more particularly, to semiconductors with latch-up immunity structure, and methods of creation thereof.

### Description of Related Art

The continuous miniaturization of transistors and their increasing density on chips epitomize the semiconductor industry's innovation, largely adhering to Moore's Law. This trend has led to transistors shrinking to nanometer scales, allowing millions and even billions to fit on a single chip, significantly enhancing computational power and energy efficiency. Various functionalities, including processing and storage, are increasingly being integrated within a single chip, enabling more compact and efficient systems.

### SUMMARY

According to an embodiment, a semiconductor device includes a first backside contact on a first side of the passive device, a second backside contact on a second side of the passive device, a first doped region over the first backside contact and on a backside of the passive device, a second doped region over the second backside contact and located on the backside of the passive device, a first well region over the first doped region, a second well region over the second doped region and a shallow trench isolation (STI) above the first well region and the second well region.

In one embodiment, the passive device further includes a bottom dielectric layer (BILD) between the first backside contact and the second backside contact, a first metal interconnect and a second metal interconnect connecting the first backside contact and the second backside contact to a backside power delivery network (BSPDN), respectively.

In one embodiment, the semiconductor device includes a set of P-type doped regions and a set of N-type doped regions over the STI and the doped well region, a first set of gate regions.

In one embodiment, the passive device is electrically connected to a back end of line (BEOL) through a first contact.

In one embodiment, the semiconductor device includes an active device having source/drain regions, a second set of gate regions, and a second contact.

In one embodiment, the active device is electrically connected to a back end of line (BEOL).

In one embodiment, the active device includes alternative layers extended horizontally between two adjacent source/drain regions.

In one embodiment, the alternative layers include silicon.

In one embodiment, the passive device is an electrostatic discharge (ESD) diode.

According to an embodiment, a method of fabricating a semiconductor device includes forming a passive device including forming a first backside contact on a first side of the passive device, forming a second backside contact on a second side of the passive device, forming a first doped region over the first backside contact and on a backside of the passive device, forming a second doped region over the second backside contact and located on the backside of the passive device, forming a first well region over the first doped region, forming a second well region over the second doped region, and forming a shallow trench isolation (STI) above the first well region and the second well region.

In one embodiment, the method includes forming a bottom dielectric layer (BILD) between the first backside contact and the second backside contact, and forming a first metal interconnect and a second metal interconnect connecting the first backside contact and the second backside contact to a backside power delivery network (BSPDN), respectively.

In one embodiment, the method includes forming a set of P-type doped regions and a set of N-type doped regions over the STI and the doped well region, and forming a first set of gate regions.

In one embodiment, the method includes establishing an electrical connection between the passive device and a back end of line (BEOL) through a first contact.

In one embodiment, the method includes forming an active device, including forming source/drain regions, forming a second set of gate regions between the source/drain regions, and forming a second contact over each of the source/drain regions.

In one embodiment, the method includes forming alternative layers extended horizontally between two adjacent source/drain regions.

In one embodiment, the method includes establishing an electrical connection between the active device and a back end of line (BEOL).

According to an embodiment, a semiconductor device includes a passive device, having a first backside contact on a first side of the semiconductor device, a second backside contact on a second side of the semiconductor device, a first doped region over the first backside contact and on a backside of the passive device, a second doped region over the second backside contact and located on the backside of the passive device, a first metal interconnect and a second metal interconnect connecting the first backside contact and the second backside contact to a backside power delivery network (BSPDN), respectively.

In one embodiment, the semiconductor device includes a shallow trench isolation (STI) above the first well region and the second well region, and a bottom dielectric layer (BILD) between the first backside contact and the second backside contact.

In one embodiment, the semiconductor device includes a first well region over the first doped region, a second well region over the second doped region.

In one embodiment, the semiconductor device includes an active device having source/drain regions, gate regions, and a contact.

These and other features will become apparent from the following detailed description of illustrative embodiments thereof, which is to be read in connection with the accompanying drawings.

### BRIEF DESCRIPTION OF THE DRAWINGS

The drawings are of illustrative embodiments. They do not illustrate all embodiments. Other embodiments may be used in addition or instead. Details that may be apparent or unnecessary may be omitted to save space or for more effective illustration. Some embodiments may be practiced with additional components or steps and/or without all the components or steps that are illustrated. When the same numeral appears in different drawings, it refers to the same or like components or steps.

FIGS. 1A-1C illustrate the latch-up formation, the undershoot and overshoot scenarios in a conventional semiconductor device.

FIGS. 1D-1E illustrate a self-protected device and a non-self-protected device.

FIG. 1F illustrates a latch-up prone region of a convectional semiconductor device.

FIG. 2 illustrates a semiconductor device, in accordance with some embodiments.

FIG. 3 illustrates a semiconductor device after the formation of the front end of line, middle end of line, and back end of line, in accordance with some embodiments.

FIG. 4 illustrates a semiconductor device after wafer flip and substrate removal, in accordance with some embodiments.

FIG. 5 illustrates a semiconductor device after patterning of the backside of the semiconductor device, in accordance with some embodiments.

FIG. 6 illustrates a semiconductor device after the formation of the spacer layer, in accordance with some embodiments.

FIG. 7 illustrates a semiconductor device after the removal of the mask, in accordance with some embodiments.

FIG. 8 illustrates a semiconductor device after the removal of the substrate, in accordance with some embodiments.

FIG. 9 illustrates a semiconductor device after the formation of the backside interlayer dielectric, in accordance with some embodiments.

FIG. 10 illustrates a semiconductor device after the formation of the doped regions, in accordance with some embodiments.

FIG. 11 illustrates a semiconductor device after the formation of additional backside interlayer dielectric, in accordance with some embodiments.

FIG. 12 illustrates a semiconductor device after the formation of the backside interconnect, in accordance with some embodiments.

FIG. 13 illustrates a semiconductor device after the removal of the placeholders, in accordance with some embodiments.

FIG. 14 illustrates a semiconductor device after the backside contact formation, in accordance with some embodiments.

FIG. 15 illustrates a semiconductor device after the formation of the backside interconnect, in accordance with some embodiments.

FIG. 16 illustrates a block diagram of a method for forming the semiconductor device, in accordance with some embodiments.

### DETAILED DESCRIPTION

### Overview

In the following detailed description, numerous specific details are set forth by way of examples to provide a thorough understanding of the relevant teachings. However, it should be apparent that the present teachings may be practiced without such details. In other instances, well-known methods, procedures, components, and/or circuitry have been described at a relatively high-level, without detail, to avoid unnecessarily obscuring aspects of the present teachings.

In one aspect, spatially related terminology such as “front,” “back,” “top,” “bottom,” “beneath,” “below,” “lower,” above,” “upper,” “side,” “left,” “right,” and the like, is used with reference to the orientation of the Figures being described. Since components of embodiments of the disclosure can be positioned in a number of different orientations, the directional terminology is used for purposes of illustration and is in no way limiting. Thus, it will be understood that the spatially relative terminology is intended to encompass different orientations of the device in use or operation in addition to the orientation depicted in the figures. For example, if the device in the figures is turned over, elements described as “below” or “beneath” other elements or features would then be oriented “above” the other elements or features. Thus, for example, the term “below” can encompass both an orientation that is above, as well as below. The device may be otherwise oriented (rotated 90 degrees or viewed or referenced at other orientations) and the spatially relative descriptors used herein should be interpreted accordingly.

As used herein, the terms “lateral” and “horizontal” describe an orientation parallel to a first surface of a chip.

As used herein, the term “vertical” describes an orientation that is arranged perpendicular to the first surface of a chip, chip carrier, or semiconductor body.

As used herein, the terms “coupled” and/or “electrically coupled” are not meant to mean that the elements must be directly coupled together—intervening elements may be provided between the “coupled” or “electrically coupled” elements. In contrast, if an element is referred to as being “directly connected” or “directly coupled” to another element, there are no intervening elements present. The term “electrically connected” refers to a low-ohmic electric connection between the elements electrically connected together.

Although the terms first, second, etc., may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

Example embodiments are described herein with reference to cross-sectional illustrations that are schematic illustrations of idealized or simplified embodiments (and intermediate structures). As such, variations from the shapes of the illustrations as a result, for example, of manufacturing techniques and/or tolerances, may be expected. Thus, the regions illustrated in the figures are schematic in nature and their shapes do not necessarily illustrate the actual shape of a region of a device and do not limit the scope.

It is to be understood that other embodiments may be used and structural or active changes may be made without departing from the spirit and scope defined by the claims. The description of the embodiments is not limiting. In particular, elements of the embodiments described hereinafter may be combined with elements of different embodiments.

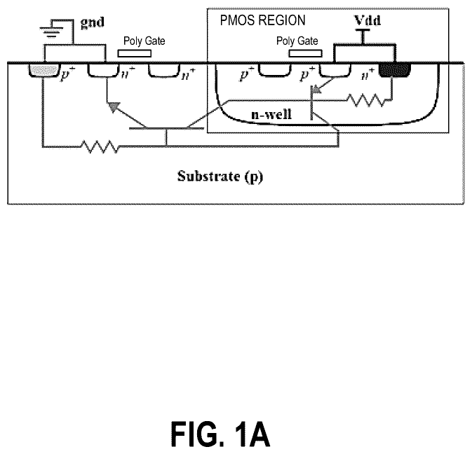

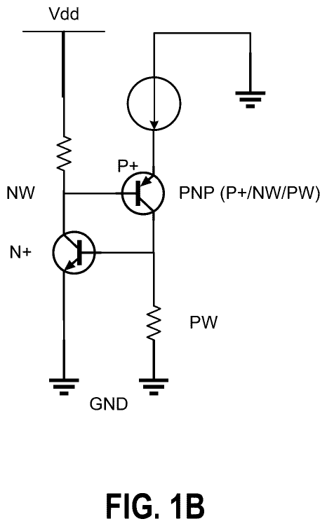

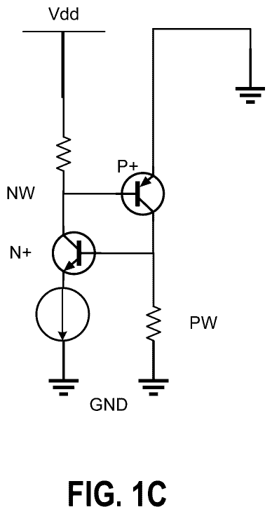

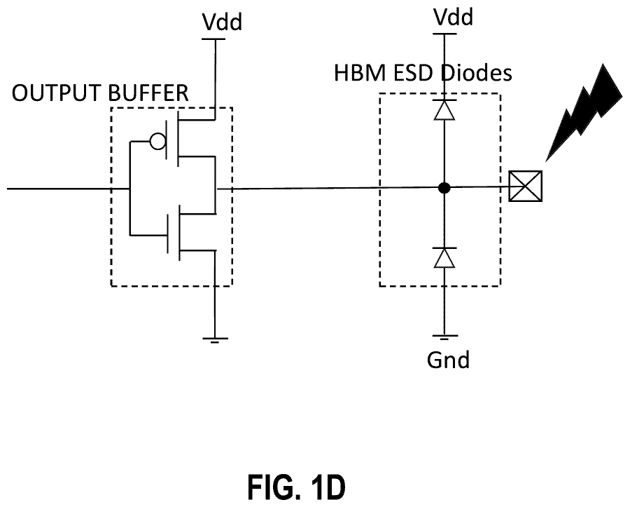

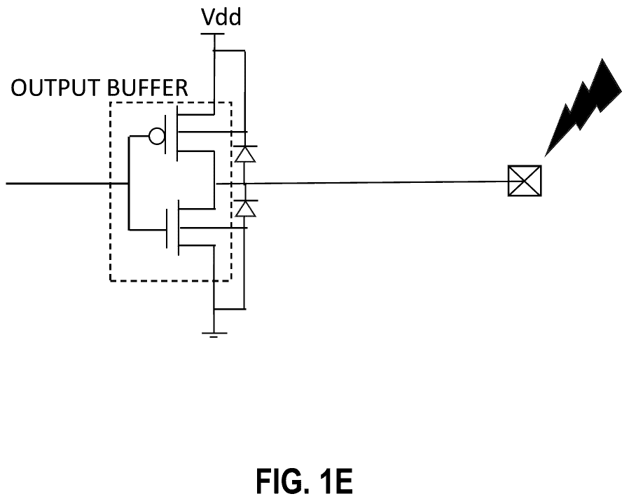

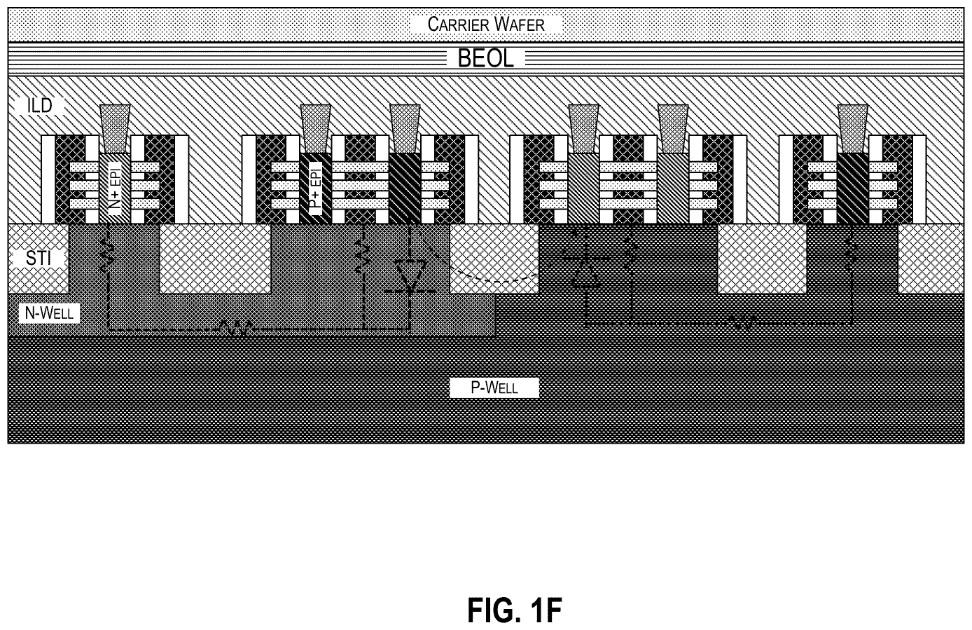

Backside interconnect is recognized as the industry go-to direction for advancing semiconductor technology. By routing interconnections on the backside of the semiconductor wafer, this approach effectively increases the available area for active device components on the frontside, thereby enhancing overall device performance and density. The implementation of backside interconnects allows for more efficient power distribution and signal routing, reducing resistance and inductance associated with longer interconnect paths. Preventing latch-up in integrated circuits is desired due to its potential to cause catastrophic failure. Latch-up refers to the inadvertent creation of a low-impedance path between the power supply rails, typically triggered by certain electrical conditions such as overshoot, undershoot, or transient currents. This low-impedance path can lead to excessive current flow, causing overheating, circuit malfunction, or permanent damage to the integrated circuit. Effective latch-up prevention strategies require careful layout design, proper isolation techniques, and the incorporation of guard rings or substrate ties to mitigate the risk of latch-up occurrences. FIGS. 1A-1C illustrate the latch-up formation, the undershoot and overshoot scenarios in a conventional semiconductor device. FIGS. 1D-1E illustrate a self-protected device and a non-self-protected device. FIG. 1F illustrates a latch-up prone region of a convectional semiconductor device. In semiconductor devices, overshoot and undershoot are phenomena that can adversely affect signal integrity. Overshot occurs when the voltage of a signal exceeds its intended maximum value during a transition, often due to the inductive and capacitive properties of the interconnects. This excessive voltage can lead to signal distortion, potential damage to the device, and increased electromagnetic interference (EMI). Similarly, undershoot refers to the scenario where the signal voltage drops below its intended minimum value, which can also cause signal integrity issues, increased susceptibility to noise, and potential triggering of unintended states in digital circuits. Both overshoot and undershoot need to be considered in high-speed and high-frequency circuit design, necessitating the use of proper termination techniques, controlled impedance routing, and careful signal integrity analysis to minimize their impact.

The parasitic PNPN SCR structure in complementary metal-oxide-semiconductor (CMOS) technology is a factor in latch-up phenomena. The parasitic SCR is formed inadvertently during the fabrication of CMOS devices, including a PNP transistor and an NPN transistor that are interconnected in such a way that they can form a positive feedback loop. When certain conditions, such as high current injection or excessive voltage, are met, this feedback loop can become self-sustaining, leading to a latch-up condition. Once triggered, the parasitic SCR can conduct a significant amount of current, resulting in elevated temperatures, potential destruction of the device, and failure of the integrated circuit.

Preventing latch-up is important in integrated circuits because latch-up can lead to catastrophic failure of the device. One method to prevent latch-up is by reducing the resistances of the N-well and P-well regions in the semiconductor substrate. Incorporating heavily doped N+ and P+ junctions into these well regions achieves this reduction. The N+ regions decrease the resistance of the N-well, while the P+ regions lower the resistance of the P-well. By minimizing these resistances, the voltage drops that could trigger the parasitic thyristor action are reduced, thereby preventing latch-up from occurring.

Unlike conventional methods that require guard rings or additional spacing—which consume significant chip area—the use of N+/P+ junctions allows for placement in various regions of the chip without substantial area penalty. The flexibility enables designers to strategically position these junctions wherever necessary to effectively prevent latch-up while conserving valuable chip real estate.

Additionally, reducing the area occupied by well regions contributes to a smaller overall chip size. Minimizing the well regions not only saves space but also improves the performance of the integrated circuit by decreasing parasitic capacitance and resistance. This optimization is especially beneficial in high-density chip designs where maximizing functionality within a limited area is important. Integrating electrostatic discharge (ESD) protection diodes on the backside of the semiconductor wafer further decreases the implementation area required on the front side of the chip. By relocating ESD protection structures to the backside, more surface area becomes available for active circuitry and other critical components on the front side. This backside integration enhances the efficient use of chip area and can improve the overall performance and reliability of the integrated circuit.

The disclosed semiconductor device incorporates low-resistance well contacts designed to improve latch-up prevention and enable self-protected electrostatic discharge (ESD) devices within backside power delivery network in order to minimize high current flow between the power supply rails (VDD and GND) which can cause device malfunction, overheating, or even permanent damage to the integrated circuit.

By implementing low-resistance well contacts, the semiconductor device effectively reduces the resistivity of the N-well and P-well regions within the semiconductor substrate. These well contacts are heavily doped regions that provide efficient electrical pathways, minimizing voltage drops across the wells during operation. Reducing the resistance in the well regions decreases the likelihood of triggering the parasitic thyristor action responsible for latch-up. Lower resistivity in the wells diminishes local voltage differences that can forward-bias the parasitic p-n-p-n structure, thereby preventing its unintended activation.

In addition to improving latch-up immunity, the low-resistance well contacts play a role in enabling self-protected ESD devices. ESD events introduce sudden voltage spikes that can damage sensitive semiconductor components. By incorporating low-resistance paths through the well contacts, the device can more effectively shunt ESD currents away from vulnerable areas, enhancing the ESD robustness of the integrated circuit. The self-protection mechanism relies on the device's ability to handle ESD events internally without the need for additional external protection components, simplifying the design and reducing the overall area required on the chip.

Integrating these features within backside power delivery network technology further enhances the device's performance. Traditional semiconductor devices typically have power delivery networks located on the front side of the chip, which can lead to interconnect congestion and increased parasitic resistances and inductances.

Backside power delivery networks allow for more direct and shorter paths for power supply connections, reducing the resistance and inductance associated with power distribution. This improvement is particularly beneficial in advanced semiconductor technologies where scaling down device dimensions leads to increased current densities and power consumption challenges. The low-resistance well contacts complement the backside power delivery by ensuring that the reduced resistance benefits extend throughout the device, from the power supply connections to the active regions within the semiconductor.

Accordingly, the teachings herein provide methods and systems of semiconductor device formation with the latch-up immunity structure. The techniques described herein may be implemented in a number of ways. Example implementations are provided below with reference to the following figures.

### Example Semiconductor Device With Latch Up Immunity Structure

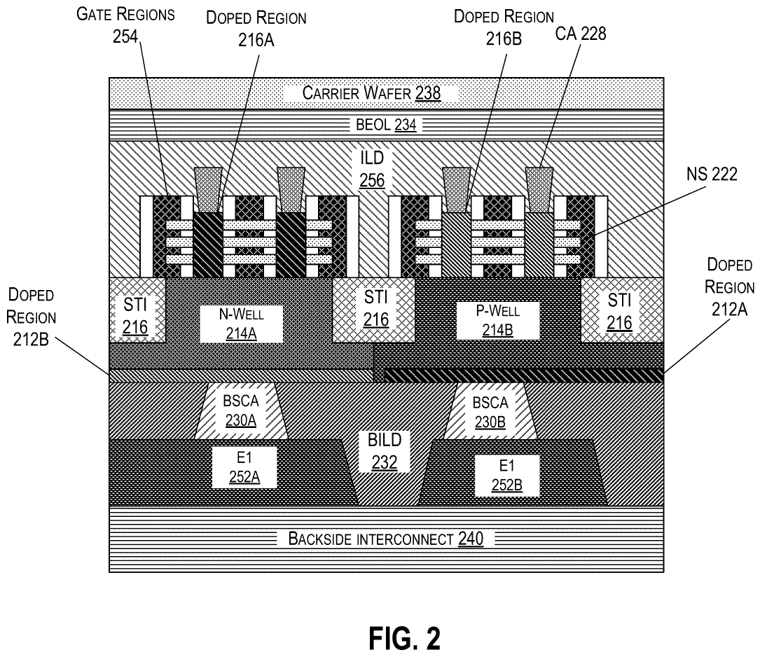

Reference now is made to FIG. 2, which is a simplified cross-section view of a semiconductor device, consistent with an illustrative embodiment. The semiconductor device integrates both a passive electrostatic discharge (ESD) protection section, e.g., the passive section, and an active operational section, e.g., the active section. The passive section serves as the ESD protection, includes a first backside contact, BSCA 230A, on one side and a second backside contact, BSCA 230B, on the opposite side. The BSCA 230A and BSCA 230B establish electrical connections from the backside of the semiconductor device, enhancing current flow and signal transmission efficiency. The semiconductor device can further include frontside contacts, CA 228.

Over each backside contact is a first doped region 212A and a second doped region 212B, respectively, situated on the backside of the passive device. The first doped region 212A and the second doped region 212B are areas where impurities have been introduced to modify the electrical properties of the semiconductor material. By doping the doped regions with specific elements—such as phosphorus for N-type doping or boron for P-type doping—the conductivity is enhanced, allowing for precise control over the device's electrical characteristics.

Above the first doped region 212A and the second doped region 212B are a first well region 214A and a second well region 214B, respectively. The well regions serve multiple purposes, including providing isolation between different parts of the device and forming the necessary p-n junctions for semiconductor operation. The well regions are doped differently from the underlying regions to create these junctions, which are fundamental for controlling the flow of charge carriers (electrons and holes) within the semiconductor device.

Each pair of first doped region 212A and the second doped region 212B can be created by doping two regions, one with a type P dopant, which introduces an excess of positive charge carriers (holes), and the other with a type N dopant, which introduces an excess of negative charge carriers (electrons). An N-well region and a P-well region can form the p-n junction of the semiconductor device. The p-n junction can control the flow of electrical current within the semiconductor device. The p-n junction can be created by doping two adjacent regions, one with a type P dopant, which introduces an excess of positive charge carriers (holes), and the other with a type N dopant, which introduces an excess of negative charge carriers (electrons). At the interface between the P and N regions, a depletion region forms due to the diffusion of electrons from the N region into the P region and the diffusion of holes in the opposite direction. Such a diffusion process continues until the electric field created by the accumulation of charge at the junction balances the diffusion forces, resulting in a zone depleted of free charge carriers. In its natural state, the p-n junction allows current to flow more easily in one direction than in the opposite.

When forward biased, i.e., positive voltage applied to the P side relative to the N side, the depletion region narrows, lowering the barrier for charge carriers to move across the junction, and allowing current to flow through the device. Conversely, when reverse-biased, i.e., negative voltage applied to the P side, the depletion region widens, increasing the barrier for charge movement, and significantly reducing the flow of current.

Shallow trench isolation, STI 216, is situated above the first well region 214A and the second well region 214B. The STI 216 can include a dielectric material, such as silicon dioxide, that electrically isolates different regions of the semiconductor device to prevent electrical interference and leakage currents. STI 216 can facilitate confining electrical currents to their intended paths, ensuring the passive device operates reliably without crosstalk between adjacent components.

Between the BSCA 230A and the BSCA 230B lies a bottom dielectric layer, BILD 232. The BILD 232 acts as an insulating layer that prevents unwanted electrical interactions between the backside contacts, and enhances electrical isolation within the device and reduces parasitic capacitance, which can adversely affect performance, especially at high frequencies. The BILD 232 helps prevent unintended interactions between different conductive regions, thereby improving overall device performance.

Connecting the BSCA 230A and BSCA 230B to a backside power delivery network, BSPDN are a first metal interconnect, E1 252A, and a second metal interconnect, E1 252B, respectively. The BSPDN can be a network of conductors, e.g., backside interconnect 240, on the backside of the semiconductor device that distributes power efficiently across the device. By connecting the passive device directly to the BSPDN, power delivery is improved, and voltage drops are minimized, enhancing the overall efficiency and performance of the device.

Over the STI 216, the first well region 214A, and the second well region 214B, there is a set of P-type doped regions 216A and a set of N-type doped regions 216B. These doped regions form the active areas of transistors, such as the source and drain regions in metal-oxide-semiconductor field-effect transistors (MOSFETs). The set of P-type doped regions 216A have an abundance of holes as charge carriers, while the set of N-type doped regions 216B have an excess of electrons. The precise arrangement and doping of these regions allow for the formation of p-n junctions and the control of electrical currents within the device.

A first set of gate regions 254 is included above the doped regions. The first set of gate regions 254 can be made of conductive materials such as polysilicon or metal and are insulated from the underlying semiconductor by a thin dielectric layer known as the gate oxide. When a voltage is applied to the gate, it modulates the conductivity of the channel beneath it, allowing the device to switch between conducting and non-conducting states. This mechanism is fundamental to the operation of transistors in digital and analog circuits.

In some embodiments, alternative layers, e.g., nanosheet gates, NS 222, can extend horizontally between adjacent doped regions, which may include silicon due to its semiconducting properties essential for controlling the flow of electrical current within the device.

The semiconductor device is electrically connected to the back end of line, BEOL 234, through a contact, CA 228. The BEOL 234 can include the upper layers of the semiconductor device, where metal interconnections such as various components and allow for external connections. The contacts ensure that both the passive and active components are properly integrated into the overall circuitry of the device.

The CA 228, located over doped regions can establish connections between the semiconductor device and the BEOL 234. The CA 228 can ensure efficient electrical routing and connectivity within the semiconductor device. The fabrication of the CA 228 can involve lithography and etching processes to define the contact area. The CA 228 can be made using conductive materials such as copper (Cu) or tungsten (W).

The semiconductor device can include several structural and functional elements that contribute to its performance and integration within semiconductor technology. The semiconductor device can further include an interlayer dielectric, ILD 256, situated above the STI 216. The ILD 256 can serve as an insulating layer that separates various conducting layers and components within the semiconductor device. The ILD 256 can be a layer of insulating material to electrically isolate and provide mechanical support between different layers of conducting and active components. The ILD 256 can enable efficient signal transmission, reduce crosstalk, and ensure the proper functioning of the semiconductor device. In an embodiment, the ILD 256 can electrically isolate adjacent conducting layers or active components in the semiconductor device. By providing insulation between different layers, the ILD 256 can prevent electrical shorts, reduce (e.g., minimize) leakage current, and ensure that signals are directed only along the desired pathways. In some embodiments, the ILD 256 can help reduce parasitic capacitance between adjacent metal interconnects or active devices and provide mechanical support to the passive device's structure.

In several embodiments, the BILD 232 can provide structural support to the semiconductor device by maintaining the mechanical integrity and stability of the semiconductor device. The BILD 232 can further help prevent the warping, bending, or cracking of the substrate, particularly during the manufacturing process or subsequent handling. The BILD 232 can ensure that the semiconductor device remains mechanically robust and maintains its dimensional stability.

In an embodiment, the BILD 232 can also serve as a planarization layer in the semiconductor device fabrication process. As various layers are deposited and patterned on the front side of the semiconductor device, irregularities or topographic variations may arise. The BILD 232 can be used to smoothen the surface, creating a more planar substrate for subsequent processing steps, such as metal interconnect deposition or bonding. In some embodiments, a low dielectric constant BILD material can be utilized to reduce signal delays, crosstalk, and power consumption in high-speed and high-frequency circuits. By optimizing the dielectric constant, the BILD 232 can contribute to improved overall passive device performance. In several embodiments, BILD 232 can facilitate wafer-level testing of the semiconductor device. By providing electrical isolation between the active regions and the backside contact, individual passive device or elements on the semiconductor device can be electrically accessed and tested without interference from neighboring devices or components. This enables efficient and accurate wafer-level testing, ensuring quality control during semiconductor manufacturing. The semiconductor device can further include a carrier wafer 238.

In some embodiments, the semiconductor device incorporates a vertically integrated structure that enables the seamless integration of electrostatic discharge (ESD) diodes into input/output (IO) p-type field-effect transistors (PFETs) and n-type field-effect transistors (NFETs). This design allows the ESD protection diodes to be embedded directly within the IO transistors, improving space efficiency and simplifying the overall architecture.

In such a structure, the N+ and P+ epitaxial junctions, along with their contacts and associated metal wiring, are formed on the backside of the semiconductor wafer, positioned directly beneath the PFET and NFET devices. Specifically, for the PFETs, P+ junctions are created under the transistor on the backside, establishing a direct path for holes as charge carriers. Similarly, for the NFETs, N+ junctions are formed beneath the transistor, facilitating efficient electron flow. By moving these junctions and their contacts to the backside, the device reduces the total area occupied on the front side. This arrangement eliminates the need for extra surface space to accommodate ESD diodes and their interconnections, resulting in a more compact layout without sacrificing transistor functionality.

Additionally, placing the N-well (NW) and P-well (PW) contacts on the backside of the wafer decreases the resistances of the N-well (RNW) and P-well (RPW) significantly. In semiconductor devices, high well resistances can contribute to latch-up, a phenomenon where a parasitic thyristor structure within the integrated circuit becomes inadvertently activated. Latch-up can cause excessive current flow, leading to overheating and potentially permanent damage to the device. Reducing RNW and RPW by positioning the well contacts on the backside minimizes voltage drops across the wells during operation. Lowering the well resistances reduces the likelihood of triggering the parasitic thyristor action responsible for latch-up, thereby enhancing the device's immunity to latch-up issues without consuming valuable front-side chip area.

The vertical integration of ESD diodes into the IO transistors also improves the electrical performance of the device. With the ESD protection diodes closely integrated with the transistors, the response time during an ESD event is reduced, allowing for more immediate protection of sensitive components. The backside formation of N+ and P+ junctions ensures that the current paths during an ESD event are short and efficient, enabling the device to effectively dissipate excess charge and maintain operational integrity.

Moreover, the backside integration aids in thermal management. Heat generated during normal operation or ESD events can be dissipated more efficiently through the backside of the wafer. This improved thermal pathway helps maintain the device's performance by preventing thermal degradation, thereby extending its operational lifespan and reliability. The design of the semiconductor device offers advantages, including reduction in the total area required on the front side of the wafer, allowing for higher integration densities and additional functionality within the same chip space.

### Example Act of Fabrication of Semiconductor Device With Latch Up Immunity Structure

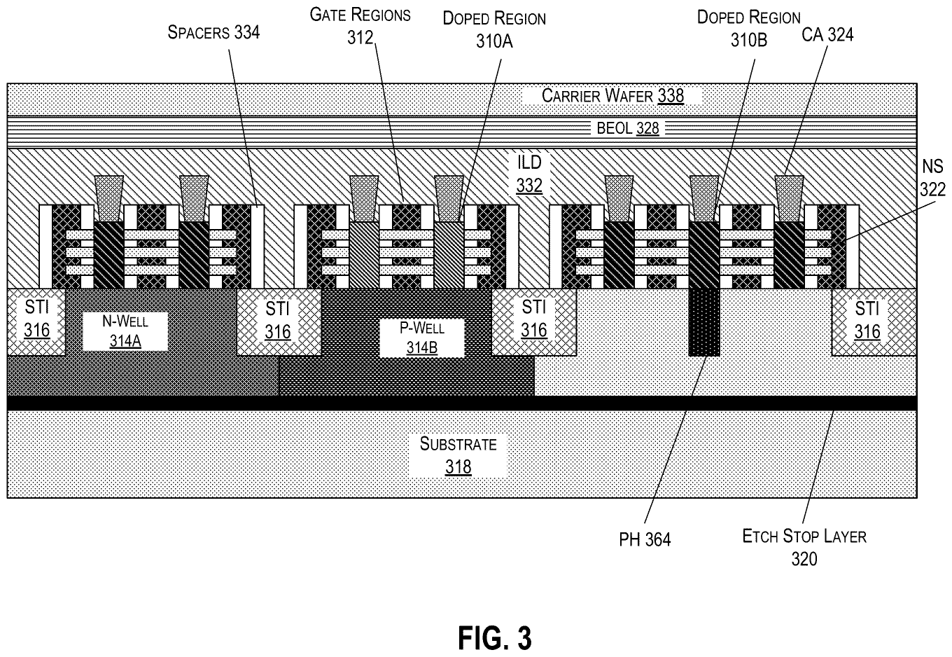

With the foregoing description of an example semiconductor device, it may be helpful to discuss an example process of manufacturing the same. To that end, FIGS. 3-15 illustrate various acts in the manufacture of a semiconductor device, consistent with illustrative embodiments.

Reference now is made to FIG. 3, which is a simplified cross-section view of a semiconductor device, after the front end of line (FEOL), middle of line (MOL), and BEOL, consistent with an illustrative embodiment. The semiconductor device can include a set of P-type doped regions 310A, a set of N-type doped regions 310B, gate regions 312, an N-well region 314A, a P-well region 314B, shallow trench isolation, STI 316, a substrate 318, an etch stop layer 320, NS 322, frontside contacts, CA 324, a back end of line, BEOL 328, an interlayer dielectric, ILD 332, spacers 334, a placeholder, PH 364, and a carrier wafer 338.

In the illustrative example depicted in FIG. 3, the semiconductor device is depicted as being on silicon as the substrate 318, while it will be understood that other types as the substrate 318 may be used as well, including, without limitation, monocrystalline Si, silicon germanium (SiGe), III-V compound semiconductor, II-VI compound semiconductor, or semiconductor-on-insulator (SOI). Group III-V compound semiconductors, for example, include materials having at least one group III element and at least one group V element, such as one or more of aluminum gallium arsenide (AlGaAs), aluminum gallium nitride (AlGaN), aluminum arsenide (AlAs), aluminum indium arsenide (AlIAs), aluminum nitride (AlN), gallium antimonide (GaSb), gallium aluminum antimonide (GaAlSb), gallium arsenide (GaAs), gallium arsenide antimonide (GaAsSb), gallium nitride (GaN), indium antimonide (InSb), indium arsenide (InAs), indium gallium arsenide (InGaAs), indium gallium arsenide phosphide (InGaAsP), indium gallium nitride (InGaN), indium nitride (InN), indium phosphide (InP) and alloy combinations including at least one of the foregoing materials. The alloy combinations can include binary (two elements, e.g., gallium (III) arsenide (GaAs)), ternary (three elements, e.g., InGaAs), and quaternary (four elements, e.g., aluminum gallium indium phosphide (AlInGaP)) alloys.

In various embodiments, the substrate 318 can include any suitable material or combination of materials, such as doped or undoped silicon, glass, dielectrics, etc. For example, the substrate may include a silicon-on-insulator (SOI) structure, e.g., with a buried insulator layer, or a bulk material substrate, e.g., with appropriately doped regions, typically referred to as wells. In another embodiment, the substrate may be silicon with silicon oxide, nitride, or any other insulating film on top.

In various embodiments, the etch stop layer 320 is formed over the substrate 318. The etch stop layer 320 can be a thin layer of material incorporated into the structure of the semiconductor device to provide a selective barrier against etching processes, preventing further removal of underlying materials during fabrication. The etch stop layer 320 can enable precise control over the etching depth and help define the desired device dimensions. The etch stop layer 320 can further provide a stopping point for the etching process, ensuring that specific layers or regions are not etched beyond a certain point, leading to accurate patterning and control of critical features. The etch stop layer 320 can create a distinct separation between different layers or components within the device structure, and prevent the undesired etching of underlying layers or materials, enabling the creation of complex, multi-layered structures with well-defined interfaces and boundaries. In some embodiments, the etch stop layer 320 acts as a protective barrier for sensitive or delicate materials to shield such materials from aggressive etchants, preventing damage or degradation during subsequent fabrication steps.

In some embodiments, prior to forming the etch stop layer 320, the substrate 318 is prepared by cleaning and removing any impurities or oxide layers. The etch stop layer 320 is deposited onto the substrate 318 using techniques such as chemical vapor deposition (CVD), physical vapor deposition (PVD), or atomic layer deposition (ALD). In an embodiment, a photoresist can be applied, exposed to a patterned mask, developed, and used as a protective layer to define the etch stop regions. The etch stop layer 320 can then be selectively etched, stopping at a predetermined depth, while protecting the underlying layers. After the etching process, the remaining photoresist can be removed through stripping techniques. While in some embodiments, SiGe is used to form the etch stop layer 320, in some embodiments, silicon nitride (SiN), silicon oxide (SiO2), or silicon oxynitride (SiON) can be used as the etch stop layer 320.

The spacers 334 can be thin insulating layers or materials placed on the sidewalls of the gate regions 312. The spacers 334 can help control the effective channel length of the latch-up prone region. In an embodiment, the spacers 334 can allow for control over the channel's conductive properties, including resistance and carrier mobility, which can contribute to improved performance of the semiconductor device. The spacers 334 can be a low-k material.

In some embodiments, the spacers 334 can act as insulating layers between the gate regions 312 and the set of N-type doped regions 310B and the set of P-type doped regions 310A. That is, the spacers 334 can help prevent current leakage or short circuits between the gate regions 312 and the set of N-type doped regions 310B and the set of P-type doped regions 310A. Such isolation can help maintain the integrity of the passive device's electrical operation and prevent unintended current flow that could negatively impact the performance of the semiconductor device and reliability.

In further embodiments, the spacers 334 can be utilized to modulate the overlapping capacitance between the gate regions 312 and the set of N-type doped regions 310B and the set of P-type doped regions 310A. Overlapping capacitance can affect the passive device's electrical characteristics, such as threshold voltage and switching behavior. Thus, by adjusting the thickness and material properties of the spacers 334 the overlapping capacitance can be optimized, which can allow for better control and modulation of the passive device's behavior. In several embodiments, the spacers 334 can help mitigate the short-channel effects by physically separating the gate regions 312 from the set of N-type doped regions 310B and the set of P-type doped regions 310A. To that end, the spacers 334 can create a barrier that restricts the extension of the electric field into the channel region. This mitigation can improve the device's performance, reduce power consumption, and enhance overall device reliability.

In an embodiment, the spacers 334 can serve as barriers that prevent the lateral diffusion of dopant atoms from the set of N-type doped regions 310B and the set of P-type doped regions 310A, and into the channel region during the doping process. Such diffusion can alter the channel characteristics and compromise the passive device's performance. By confining the dopant diffusion, the spacers 334 can contribute to maintaining the desired device's characteristics and electrical behavior. In some embodiments, the spacers 334 can be formed over the sidewalls of the gate regions 312. The spacers 334 can be formed by deposition techniques. Alternatively, the spacers 334 can be formed by etching or selectively epitaxially growing the spacers 334 over the sidewalls of the gate regions 312. In various embodiments, the spacers 334 can include SiGe. In some embodiments, the STI 316 can be made of SiN, and the ILD 332 can be made of SiO2.

In some embodiments, carrier wafer bonding, also known as wafer-to-wafer bonding or chip-to-wafer bonding, is performed to join two semiconductor devices together by creating a permanent bond between them. In some embodiments, the two semiconductor devices can be brought into contact and bonded at the atomic or molecular level, to create an interface. In an embodiment, the two semiconductor devices are brought into contact under controlled conditions, such as controlled pressure and temperature, to enable atomic or molecular bonding at the interface. Such bonding can be done at room temperature or with elevated temperatures. Alternatively, in some embodiments, an electric field and elevated temperature are utilized to create a bond. One semiconductor device can be made of semiconductor material, while the other can be a glass or silicon dioxide (SiO2) wafer. The electric field can cause ions in the glass or SiO2 to migrate and chemically bond with the semiconductor material in the other semiconductor device. In additional embodiments, a thin metal layer or metal alloy can be used as an intermediate bonding layer between the semiconductor devices.

In various embodiments, the gate regions 312 serve as control elements that regulate the flow of current through the semiconductor device. The gate regions 312 can be composed of a conductive material. The gate regions 312 can control the flow of electric current between the source and drain regions. In addition to acting as a switch, modulating the gate voltage can enable the gate regions 312 to control the current flowing through the channel region, resulting in amplified output signals.

In an embodiment, the gate regions 312 can enable the implementation of Boolean active operations, such as AND, OR, and NOT, by controlling the flow of current based on the input voltages. In some embodiments, the gate regions 312, along with other active device components, can facilitate the miniaturization and integration of electronic circuits. The ability to control the channel region's conductivity through the gate voltage allows for compact and highly efficient circuit designs.

The gate regions 312 can be formed between the set of N-type doped regions 310B and the set of P-type doped regions 310A. A replacement metal gate (RMG) process can be used to fabricate metal gate electrodes. In some embodiments, RMG can involve the replacement of the SiGe with a metal material, which can offer improved electrical performance and scalability. The metal gates can provide electrostatic control of the channel region, reduce leakage currents, and improve the semiconductor device's performance. In some embodiments, the metal gates can further provide improved control over the work function, enable matching of threshold voltages, and reduce semiconductor device variability. In order to fabricate the CA 324 portions of the ILD 332, the gate regions 312, the STI 316 are removed and filled with a suitable material to form the CA 324.

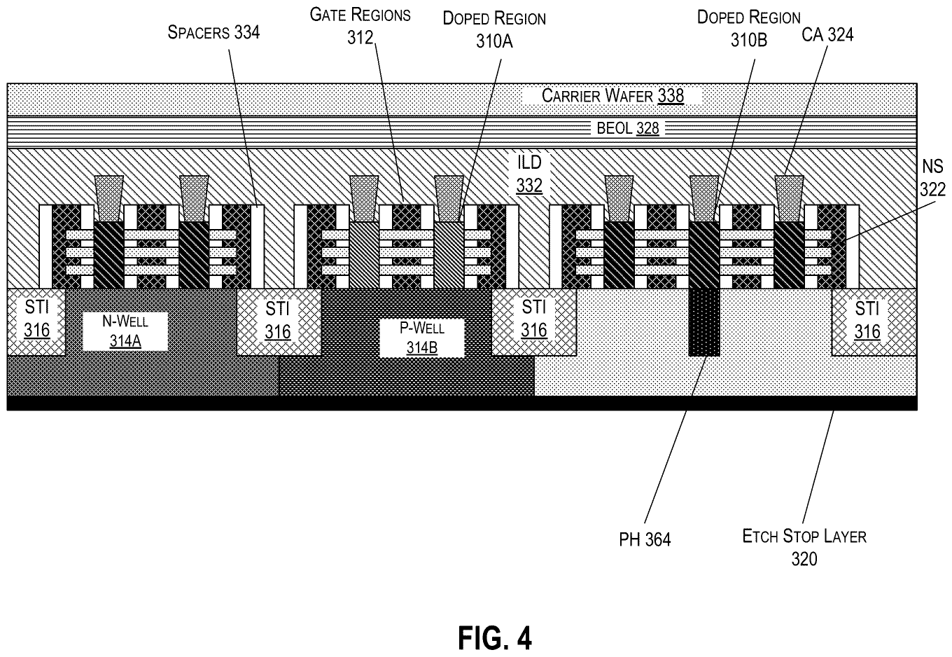

FIG. 4 illustrates a semiconductor device after the removal of the substrate, in accordance with some embodiments. In some embodiments, the semiconductor device is flipped and the substrate is removed. The substrate removal stops at the etch stop layer 320.

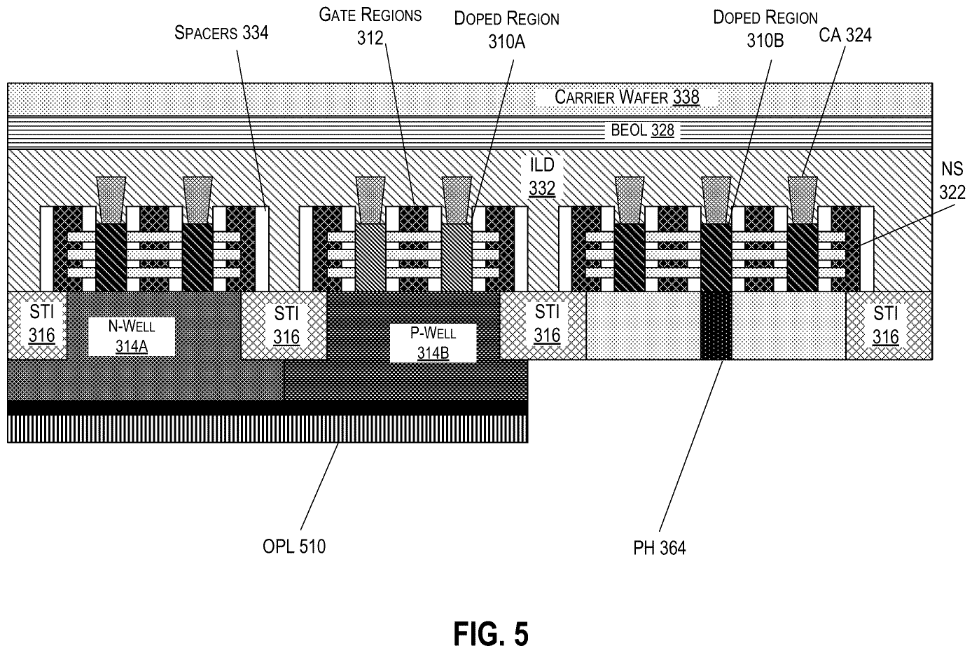

FIG. 5 illustrates a semiconductor device after the after the patterning of the substrate, in accordance with some embodiments. In some embodiments, an organic planarization layer, OPL 510, is formed over the latch-up prone region. The OPL 510 can include a photo-sensitive organic polymer having a light-sensitive material that, when exposed to electromagnetic radiation, is chemically altered and thus configured to be removed using a developing solvent. For example, in some embodiments, the photo-sensitive organic polymer can be polyacrylate resin, epoxy resin, phenol resin, polyamide resin, polyimide resin, unsaturated polyester resin, polyphenylenether resin, polyphenylenesulfide resin, or benzocyclobutene. In some embodiments, the OPL 510 can include any organic polymer and a photoactive compound having a molecular structure that can attach to the molecular structure of the organic polymer. In some embodiments, the OPL 510 material is selected to be compatible with an overlying antireflective coating and/or an overlying photoresist. In some embodiments, the OPL 510 can be applied using spin coating technology, although other techniques are within the contemplated scope of the present disclosure. Subsequently, the exposed portions of the etch stop layer are removed. Uncovered portions of the substrate and the etch stop layer are removed from the active region.

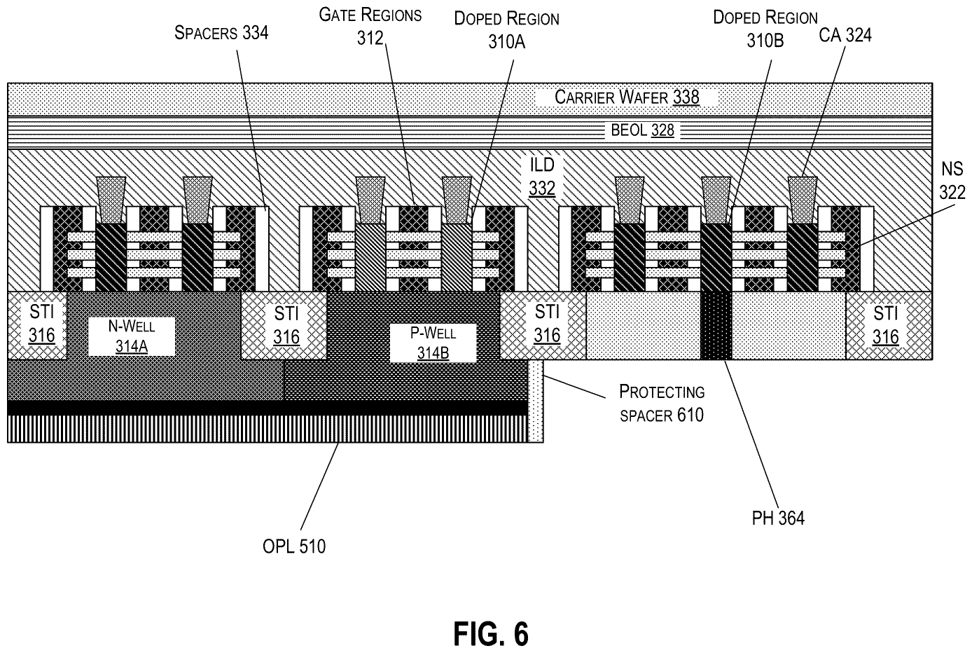

FIG. 6 illustrates a semiconductor device after the after the formation of a protective spacer layer, in accordance with some embodiments. In some embodiments, a protective spacer layer 610 is formed on the sidewalls of the patterned portions of the semiconductor device.

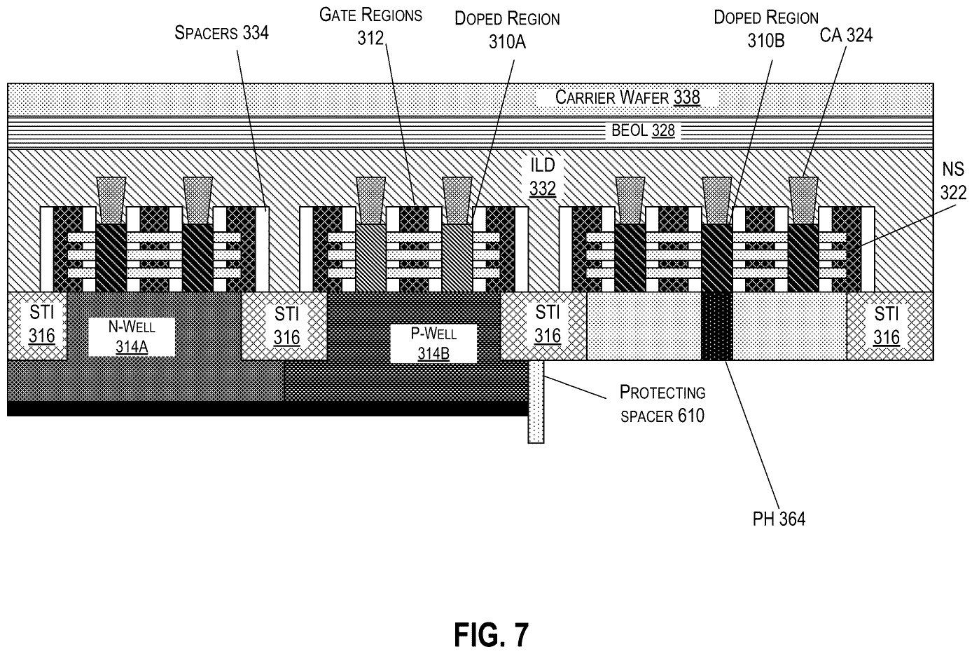

FIG. 7 illustrates a semiconductor device after the after the removal of the organic planarization layer, in accordance with some embodiments. In some embodiments, the OPL is removed.

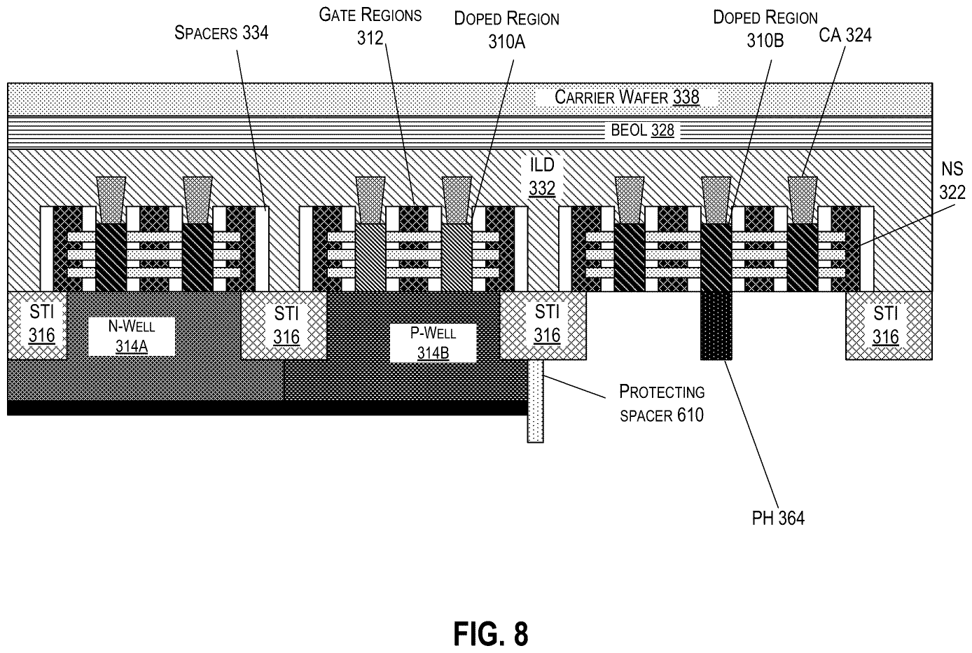

FIG. 8 illustrates a semiconductor device after the after the removal of the substrate. In some embodiments, the remaining substrate from the active region is removed.

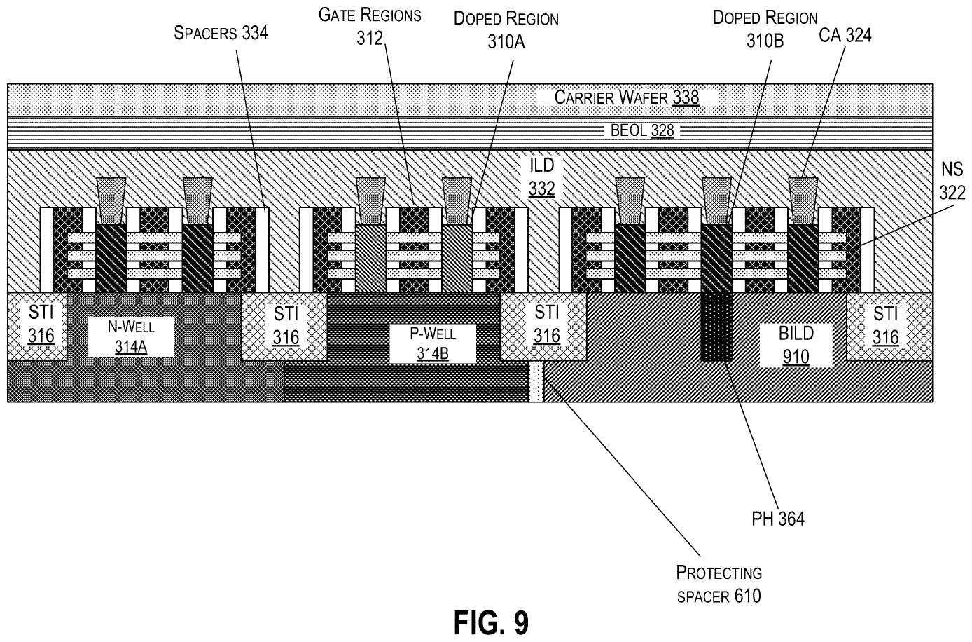

FIG. 9 illustrates a semiconductor device after the after the formation of the backside interlayer dielectric, in accordance with some embodiments. In some embodiments, the etch stop layer is removed and a BILD 910 is formed over the backside of the semiconductor device. In various embodiments, the BILD 910 can function as a protective layer, shielding the active regions of the semiconductor device from external contaminants, moisture, and mechanical stress. The BILD 910 can further help prevent physical damage, such as scratches or particle contamination, which could adversely affect semiconductor device performance. Additionally, the BILD 910 can function as a barrier against moisture ingress, which can cause corrosion and degradation of the semiconductor device's components. The BILD 910 can be made of SiO2. In an embodiment, a chemical-mechanical polishing (CMP) process is further processed after the formation of the BILD 910.

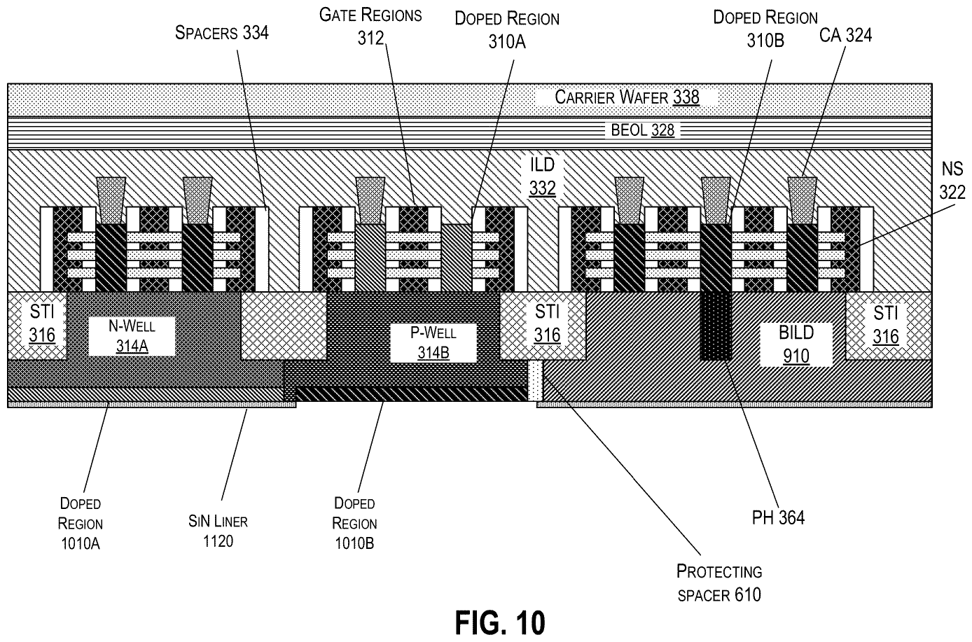

FIG. 10 illustrates a semiconductor device after the formation of doped regions, in some embodiments. In some embodiments, a first doped region 1010A is formed below the N-well region and a second doped region 1010B is formed below the P-well region. In some embodiments, an SiN liner 1120 is formed over the first doped region 1110A and the BILD 910.

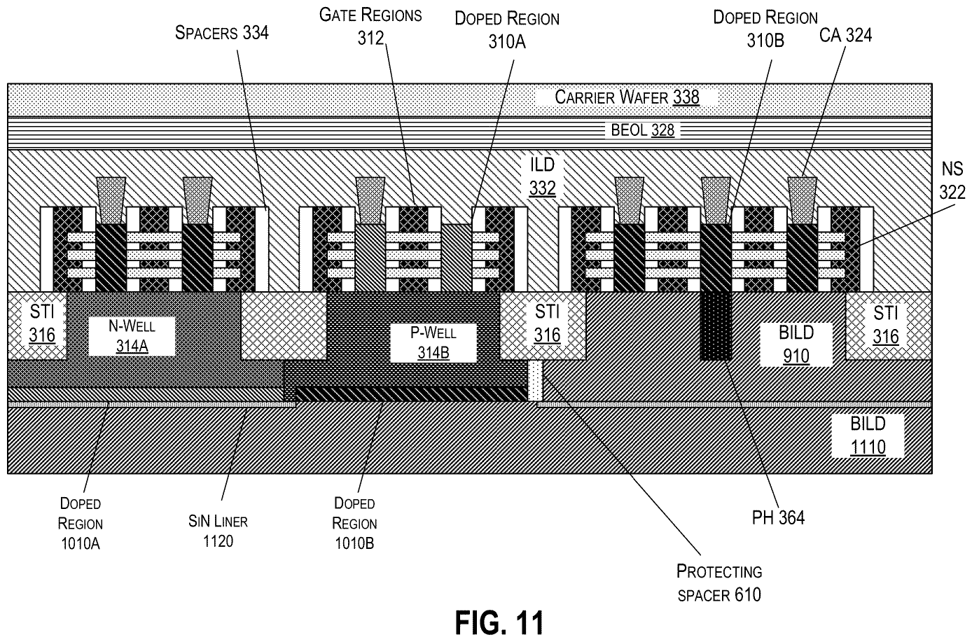

FIG. 11 illustrates a semiconductor device after the formation of additional backside interlayer dielectric, in some embodiments. In some embodiments, an additional BILD, BILD 1110, is formed over the backside of the semiconductor device.

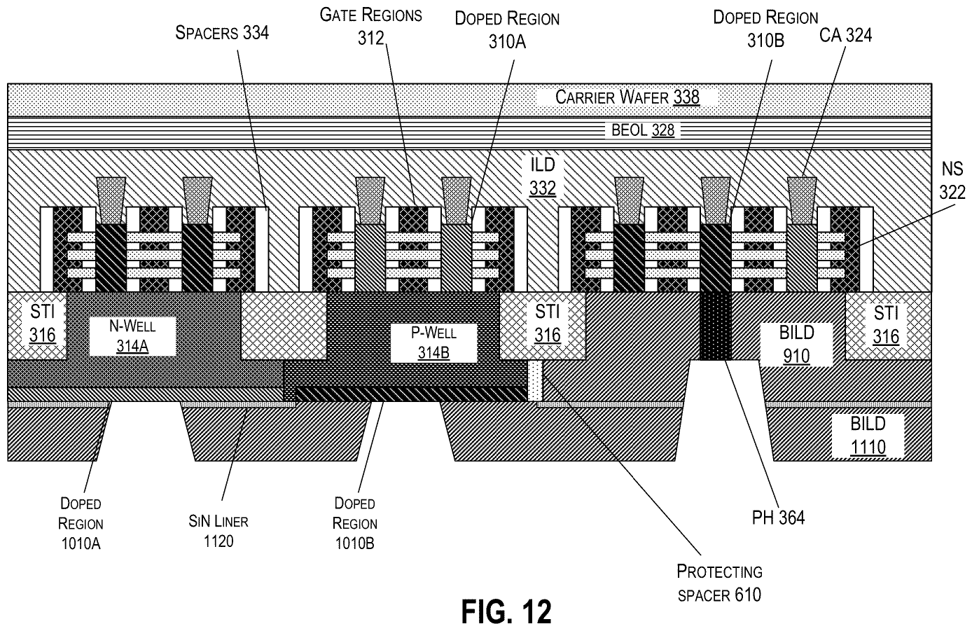

FIG. 12 illustrates a semiconductor device after the patterning of the backside interlayer dielectric, in accordance with some embodiments. In some embodiments, the BILD 1110 and BILD 910 are patterned to expose the PH 364.

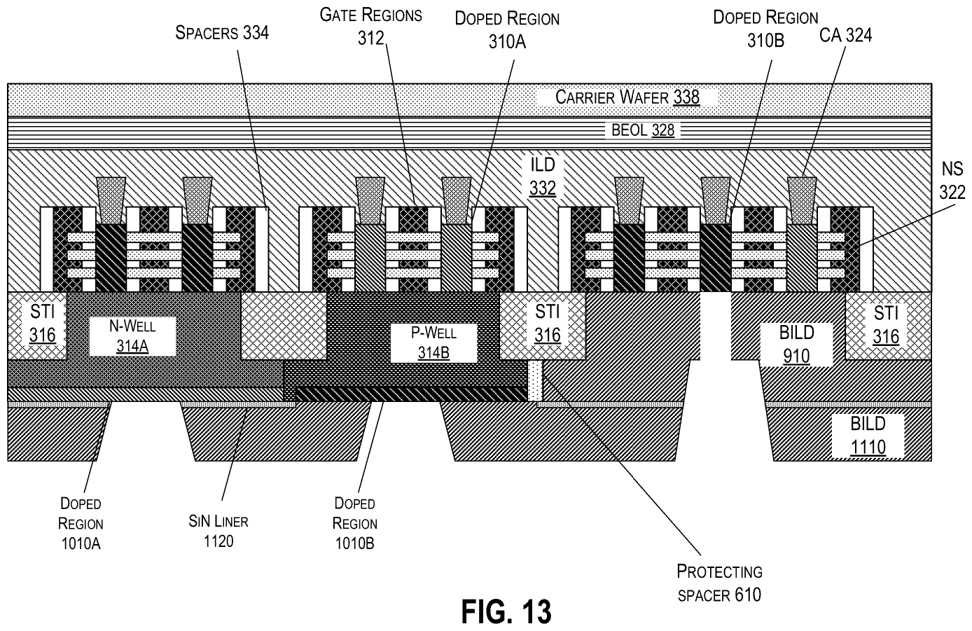

FIG. 13 illustrates a semiconductor device after the removal of the placeholder, in accordance with some embodiments. In some embodiments, the PH is removed.

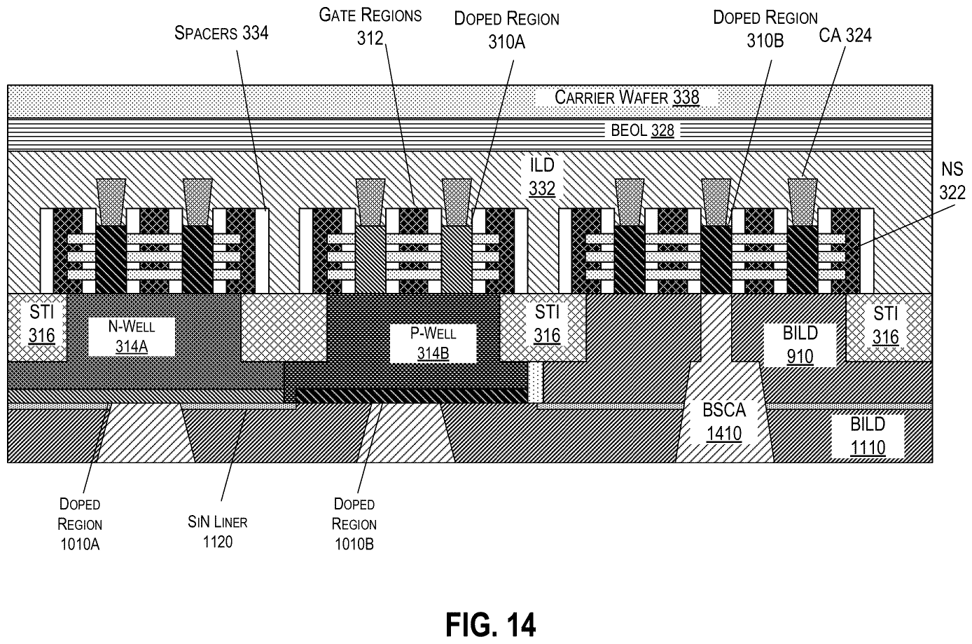

FIG. 14 illustrates a semiconductor device after the metallization of the backside contact, in accordance with some embodiments. In some embodiments, the backside contacts, BSCA 1410, are formed by filling the recessed areas with a suitable metal. The BSCA 1410 can be surrounded in by the BILD 910 and the BILD 1110.

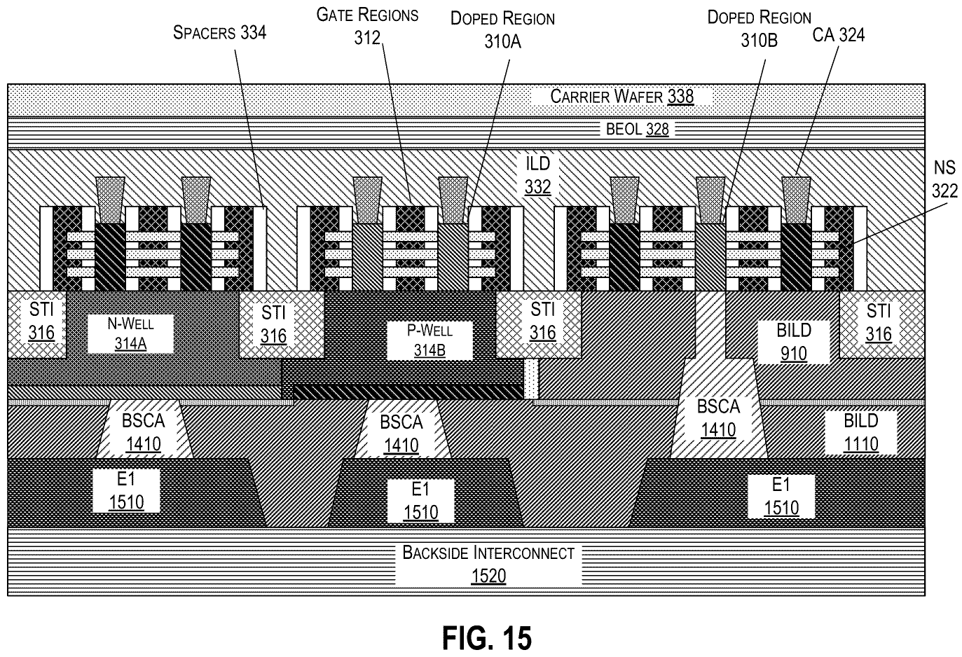

FIG. 15 illustrates a semiconductor device after the formation of the backside interconnects, in accordance with some embodiments. In some embodiments, metal interconnects, E1 1510, are formed over the BILD 1110. A backside interconnect 1520 is formed over the backside of the semiconductor device.

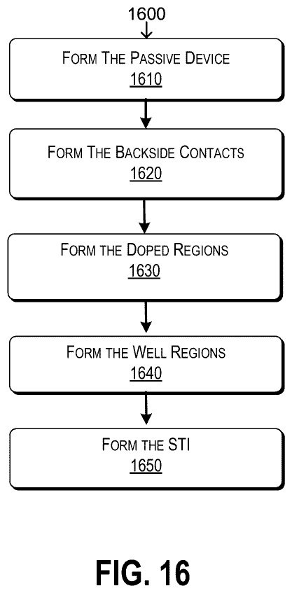

FIG. 16 illustrate a block diagram of a method 1600 for forming the semiconductor device, in accordance with some embodiments. As shown by block 1610, the passive device is formed.

As shown by block 1620, a first and a second backside contact are formed.

As shown by block 1630, a first doped region and a second doped region is formed over the first backside contact and the second backside contact, respectively.

As shown by block 1640, a first well region and a second well region are formed.

As shown by block 1650, the shallow trench isolation (STI) is formed.

In one aspect, the method and structures described above may be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip may be mounted in a single chip package (such as a plastic carrier, with leads that are affixed to a motherboard or other higher-level carrier) or in a multichip package (such as a ceramic carrier that has either or both surface interconnections or buried interconnections). In any case, the chip can then be integrated with other chips, discrete circuit elements, and/or other signal processing devices as part of either (a) an intermediate product, such as a motherboard, or (b) an end product. The end product can be any product that includes integrated circuit chips, ranging from low-end applications, such as toys, to advanced computer products having a display, a keyboard or other input device, and a central processor.

### Conclusion

The descriptions of the various embodiments of the present teachings have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to explain the principles of the embodiments, the practical application or technical improvement over technologies found in the marketplace, or to enable others of ordinary skill in the art to understand the embodiments disclosed herein.

While the foregoing has described what are considered to be the best state and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications, and variations that fall within the true scope of the present teachings.

The components, steps, features, objects, benefits, and advantages that have been discussed herein are merely illustrative. None of them, nor the discussions relating to them, are intended to limit the scope of protection. While various advantages have been discussed herein, it will be understood that not all embodiments necessarily include all advantages. Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

Numerous other embodiments are also contemplated. These include embodiments that have fewer, additional, and/or different components, steps, features, objects, benefits and advantages. These also include embodiments in which the components and/or steps are arranged and/or ordered differently.

While the foregoing has been described in conjunction with exemplary embodiments, it is understood that the term “exemplary” is merely meant as an example, rather than the best or optimal. Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any actual relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments have more features than are expressly recited in each claim. Rather, as the following claims reflect, the inventive subject matter lies in less than all features of a single disclosed embodiment. Thus, the following claims are hereby incorporated into the Detailed Description, with each claim standing on its own as a separately claimed subject matter.

What is claimed is:

1. A semiconductor device, comprising:
a passive device, comprising:
a first backside contact on a first side of the passive device;
a second backside contact on a second side of the passive device;
a first doped region over the first backside contact and on a backside of the passive device;
a second doped region over the second backside contact and located on the backside of the passive device;
a first well region over the first doped region;
a second well region over the second doped region; and
a shallow trench isolation (STI) above the first well region and the second well region.

2. The semiconductor device of claim 1, wherein the passive device further comprises:
a bottom dielectric layer (BILD) between the first backside contact and the second backside contact; and
a first metal interconnect and a second metal interconnect connecting the first backside contact and the second backside contact to a backside power delivery network (BSPDN), respectively.

3. The semiconductor device of claim 1, further comprising:
a set of P-type doped regions and a set of N-type doped regions over the STI, the first well region and the second well region; and
a first set of gate regions.

4. The semiconductor device of claim 1, wherein the semiconductor device is electrically connected to a back end of line (BEOL) through and a first contact.

5. The semiconductor device of claim 1, further comprising:
an active device, comprising:
source/drain regions;
a second set of gate regions; and
a second contact.

6. The semiconductor device of claim 5, wherein the active device is electrically connected to a back end of line (BEOL).

7. The semiconductor device of claim 1, further comprising alternative layers extended horizontally between two adjacent source/drain regions.

8. The semiconductor device of claim 7, wherein the alternative layers include silicon.

9. The semiconductor device of claim 1, wherein the passive device is an electrostatic discharge (ESD) diode.

10. A method of fabricating a semiconductor device, the method comprising:
forming a passive device comprising:
forming a first backside contact on a first side of the passive device;
forming a second backside contact on a second side of the passive device;
forming a first doped region over the first backside contact and on a backside of the passive device;
forming a second doped region over the second backside contact and located on the backside of the passive device;
forming a first well region over the first doped region;
forming a second well region over the second doped region; and
forming a shallow trench isolation (STI) above the first well region and the second well region.

11. The method of claim 10, further comprising:
forming a bottom dielectric layer (BILD) between the first backside contact and the second backside contact; and
forming a first metal interconnect and a second metal interconnect connecting the first backside contact and the second backside contact to a backside power delivery network (BSPDN), respectively.

12. The method of claim 11, further comprising:
forming a set of P-type doped regions and a set of N-type doped regions over the STI, the first well region and the second well region; and
forming a first set of gate regions.

13. The method of claim 10, further comprising establishing an electrical connection between the passive device and a back end of line (BEOL) through a first contact.

14. The method of claim 10, further comprising:
forming an active device, comprising:
forming source/drain regions;
forming a second set of gate regions between the source/drain regions; and
forming a second contact over each of the source/drain regions.

15. The method of claim 14, further comprising forming alternative layers extended horizontally between two adjacent source/drain regions.

16. The method of claim 15, further comprising establishing an electrical connection between the active device and a back end of line (BEOL).

17. A semiconductor device, comprising:
a first backside contact on a first side of the semiconductor device;
a second backside contact on a second side of the semiconductor device;
a first doped region over the first backside contact and on a backside of the semiconductor device;
a second doped region over the second backside contact and located on the backside of the semiconductor device; and
a first metal interconnect and a second metal interconnect connecting the first backside contact and the second backside contact to a backside power delivery network (BSPDN), respectively.

18. The semiconductor device of claim 17, further comprising:
a shallow trench isolation (STI) above a first well region and a second well region; and
a bottom dielectric layer (BILD) between the first backside contact and the second backside contact.

19. The semiconductor device of claim 17, further comprising:
a first well region over the first doped region; and
a second well region over the second doped region.

20. The semiconductor device of claim 17, further comprising:
an active device, comprising:
source/drain regions;
gate regions; and
a contact.
